(19) United States
(12) Patent Application Publication
(10) Pub. No.: US 2006/0110873 A1
(43) Pub. Date: May 25, 2006

(54) Method for fabricating CMOS image sensor

(75) Inventor: Chang Hun Han, Icheon-city (KR)

Correspondence Address: MCKENNA LONG & ALDRIDGE LLP, 1900 K STREET, NW, WASHINGTON, DC, 20006, US

(73) Assignee: DONGBU-ANAM SEMICONDUCTOR, Seoul (KR)

(21) Appl. No.: 11/280,318

(22) Filed: Nov. 17, 2005

(30) Foreign Application Priority Data
Nov. 19, 2004 (KR) 2004-0094975

(51) Int. Cl. H01L 21/8238

(52) U.S. Cl. 438/199

(57) ABSTRACT

Form a gate electrode on a transistor region of a first conductivity type semiconductor substrate including a photodiode region and the transistor region. Form lightly-doped second conductivity type diffusion areas at both sides of the gate electrode in the photodiode region and the transistor region. Form a screen layer over an entire surface of the semiconductor substrate including the gate electrode. Form a highly-doped second conductivity type diffusion area by planting second conductivity type impurity ions with high density to the entire surface of the semiconductor substrate using the photoresist pattern as a mask, and remove the photoresist pattern and the oxide layer.

### CROSS-REFERENCE TO RELATED APPLICATION

This application claims the benefit of Korean Application No. P2004-94975 filed on Nov. 19, 2004, which is hereby incorporated by reference as if fully set forth herein.

### BACKGROUND OF THE INVENTION

1. Field of the Invention

The present invention relates to a CMOS (Complementary Metal Oxide Silicon) image sensor, and more particularly, to a method for fabricating a CMOS image sensor which can have an improved image characteristics by decreasing an off-current of transistor.

2. Discussion of the Related Art

A CMOS image sensor is a device which adopts CMOS technology by using a control circuit, a signal processing circuit, and other components as a peripheral circuit, and forms MOS transistors corresponding to the number of unit pixels on a semiconductor substrate, so as to detect electric signals of the respective pixels using a switching method. Each pixel of the CMOS image sensor includes a photodiode and a MOS transistor. Electric signals are sequentially output from the respective pixels in the switching method, so as to display images.

Since the CMOS image sensor uses CMOS fabrication technology, the CMOS image sensor can have advantageously low power consumption and a simple fabrication method by having fewer photo process steps. In the CMOS image sensor, a control circuit, a signal processing circuit, an A/D converter circuit, and any additional components can be integrated in a CMOS image sensor chip, thereby enabling the product to be fabricated with a compact size. Accordingly, the CMOS image sensor is currently and extensively used in various applied technologies, such as digital still cameras and digital video cameras.

The CMOS image sensor is classified into 3T-type, 4T-type, and 5T-type, according to the number of transistors, wherein the 3T-type CMOS image sensor is comprised of one photodiode and three transistors, and the 4T-type CMOS image sensor is comprised of one photodiode and four transistors.

Hereinafter, an equivalent circuit and a layout for the 3T-type CMOS image sensor according to the related art will be described as follows.

FIG. 1 is an equivalent circuit diagram of the 3T-type CMOS image sensor according to the related art. FIG. 2 is a layout of one pixel in the 3T-type CMOS image sensor according to the related art.

As shown in FIG. 1, a unit pixel of the 3T-type CMOS image sensor according to the related art is comprised of one photodiode PD and three nMOS transistors T1, T2 and T3.

A cathode of the photodiode PD is connected to a drain of the first nMOS transistor T1 and a gate of the second nMOS transistor T2.

The sources of the first and second nMOS transistors T1 and T2 are connected with a power supplying line for receiving a reference voltage VR. A gate of the first nMOS transistor T1 is connected with a reset line for receiving a reset signal RST.

A source of the third nMOS transistor T3 is connected to a drain of the second nMOS transistor, and a drain of the third nMOS transistor T3 is connected to a read circuit (not shown) through a signal line. Further, a gate of the third nMOS transistor T3 is connected to a selection line for receiving a selection signal SLCT.

The first nMOS transistor Ti functions as a reset transistor Rx for resetting optical charges collected in the photodiode PD. The second nMOS transistor T2 functions as a drive transistor Dx, which also functions as a source follower buffer amplifier. The third nMOS transistor T3 is a select transistor Sx which can address signals by switching.

A predetermined portion of the reset transistor Rx, including the photodiode PD, corresponds to a non-salicide area, and the remaining portion of the reset transistor Rx corresponds to a salicide area.

In the unit pixel of the 3T-type CMOS image sensor, as shown in FIG. 2, an active area 10 is defined. One photodiode 20 is formed in a relatively large sized portion of the active area 10. Also, respective gate electrodes 30, 40 and 50 of three transistors are overlapped with the remaining portion of the active area 10.

The reset transistor Rx is formed by the gate electrode 30, the drive transistor Dx is formed by the gate electrode 40, and the select transistor Sx is formed by the gate electrode 50. Impurity ions are implanted into the active area 10 of the respective transistors, except the portions below the gate electrodes 30, 40 and 50, thereby forming source and drain regions in the respective transistors.

A power voltage Vdd is applied to the source and drain regions between the reset transistor Rx and the drive transistor Dx. The source and drain regions provided at one side of the select transistor Sx are connected with the read circuit (not shown).

Although not shown, the respective gate electrodes 30, 40 and 50 are connected with signal lines. Each end of the signal lines has a pad connected to an external driving circuit.

FIG. 3 is a cross sectional view along III-III of FIG. 2, and shows the process for forming highly doped n⁺-type diffusion area in the source and drain regions of the transistor when fabricating the CMOS image sensor according to the related art.

As shown in FIG. 3, for covering a device isolation layer 63, a lightly-doped n⁻-type diffusion area 69 of a photodiode, and a gate electrode 65, and exposing source and drain regions of transistor, highly-doped n⁺-type impurity ions are implanted to exposed portions of the source and drain regions in state of using a patterned photoresist 71 as a mask, thereby forming a highly-doped n⁺-type diffusion area 72. In FIG. 3, reference number 62 represents a lightly-doped P⁻-type epitaxial layer formed in a highly-doped P⁺⁺-type semiconductor substrate 61, reference number 64 represents a gate insulating layer, and reference number 67 represents a lightly-doped n⁻-type diffusion area formed in each of the source and drain regions.

However, the method for fabricating the CMOS image sensor according to the related art has at least the following disadvantages.

In the conventional CMOS image sensor, the three transistors of the unit pixel are circuits for transferring the signals of the photodiode. If the off-current is large, it may cause a defect in sensing the image.

When forming the n⁺-type source and drain regions, the impurity ions may be implanted into the lower side of the gate electrode, whereby the off-current may be generated.

The gate electrode is formed of polysilicon. In the crystal structure of polysilicon, atoms are regularly arranged in the three-dimensional structure. Upon implanting the impurity ions in the predetermined direction, a channeling effect may be generated. Thus, the impurity ions may be implanted to the lower side of the channel of the transistor. That is, a channel threshold voltage VT may be lowered due to undesired ion implantation, whereby the off-current may be increased.

Particularly, since the channeling effect is generated at random, it may cause the serious problems in the image sensor, thereby requiring the uniform characteristics of Vt, Idsat and Ioff of the transistor in the entire pixel array.

### SUMMARY OF THE INVENTION

Accordingly, the present invention is directed to a method for fabricating a CMOS image sensor that substantially obviates one or more problems of the related art.

The present invention can provide a method for fabricating a CMOS image sensor which may decrease an off-current by preventing impurity ions from being implanted into a lower side of a gate electrode during an ion-implantation process for forming source and drain regions.

The present invention can further provide a method for fabricating a CMOS image sensor in which an amorphous layer, formed on a surface of a silicon substrate including a gate electrode, is used as a screen layer when implanting impurity ions into source and drain regions to minimize a channeling effect and to decrease an off-current.

The present invention can also provide a method for fabricating a CMOS image sensor in which a TEOS-based oxide layer, formed on a surface of a silicon substrate including a gate electrode, is used as a screen oxide when implanting impurity ions into source and drain regions to decrease an off-current and prevent the change of device characteristics at a low temperature.

Additional aspects of the invention will be set forth in the description which follows and will become apparent to those having ordinary skill in the art.

A method for fabricating a CMOS image sensor according to the present invention can include forming a gate electrode on a transistor region of a first conductivity type semiconductor substrate including a photodiode region and the transistor region, respectively forming lightly-doped second conductivity type diffusion areas at both sides of the gate electrode in the photodiode region and the transistor region, forming a screen layer over an entire surface of the semiconductor substrate including the gate electrode, forming a photoresist pattern to cover the photodiode region and the gate electrode, forming a highly-doped second conductivity type diffusion area by implanting second conductivity type impurity ions with high density to the entire surface of the semiconductor substrate using the photoresist pattern as a mask, and removing the photoresist pattern and the oxide layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings illustrate exemplary embodiments of the invention and together with the description serve to explain the invention. In the drawings:

FIG. 1 is an equivalent circuit view of one pixel in a CMOS image sensor according to the related art;

FIG. 2 is a layout of one pixel in a CMOS image sensor according to the related art;

FIG. 3 is a cross sectional view along III-III of FIG. 2, which shows the process for forming highly doped n⁺-type diffusion area in source and drain regions of a transistor when fabricating a CMOS image sensor according to the related art;

FIGS. 4A to 4E are cross sectional views of the process for fabricating a CMOS image sensor according to an embodiment of the present invention; and

FIG. 5 is a simulation result of comparing the off-current characteristics in CMOS image sensors according to the related and according to the present invention.

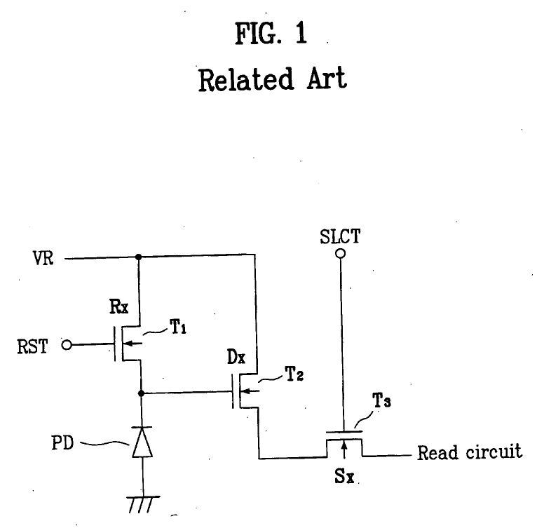

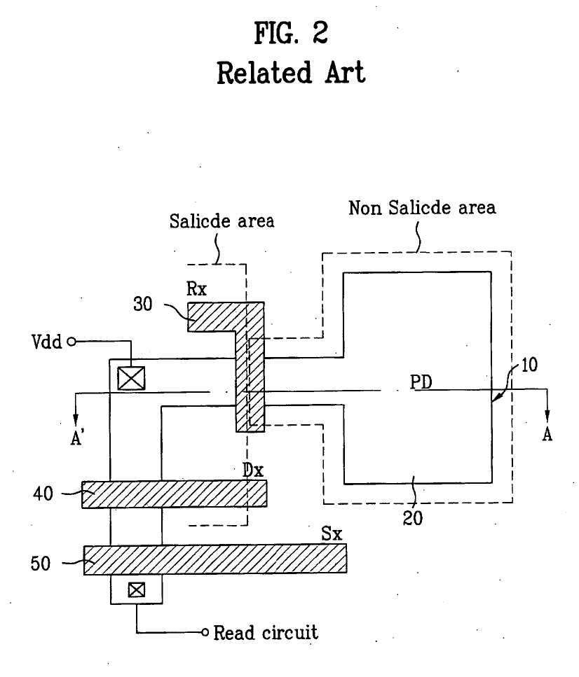

### DETAILED DESCRIPTION OF THE INVENTION

Reference will now be made in detail to exemplary embodiments of the present invention. Wherever possible, the same reference numbers will be used throughout the drawings to refer to the same or like parts.

A method for fabricating a CMOS image sensor according to the present invention will be described with reference to the accompanying drawings.

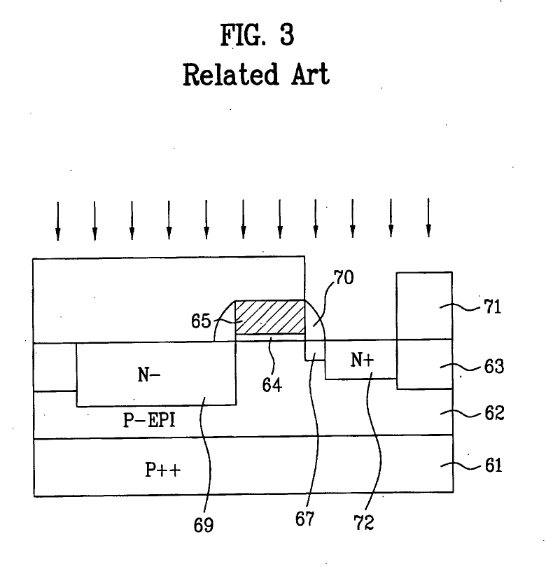

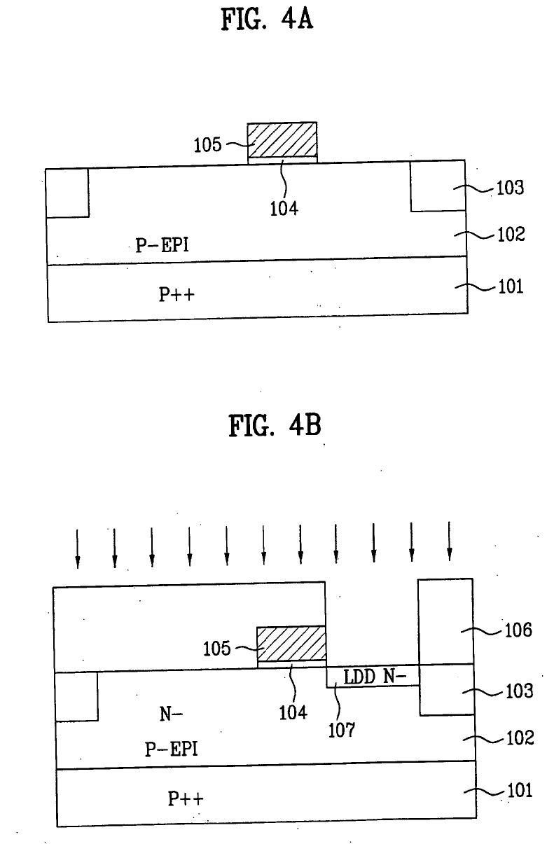

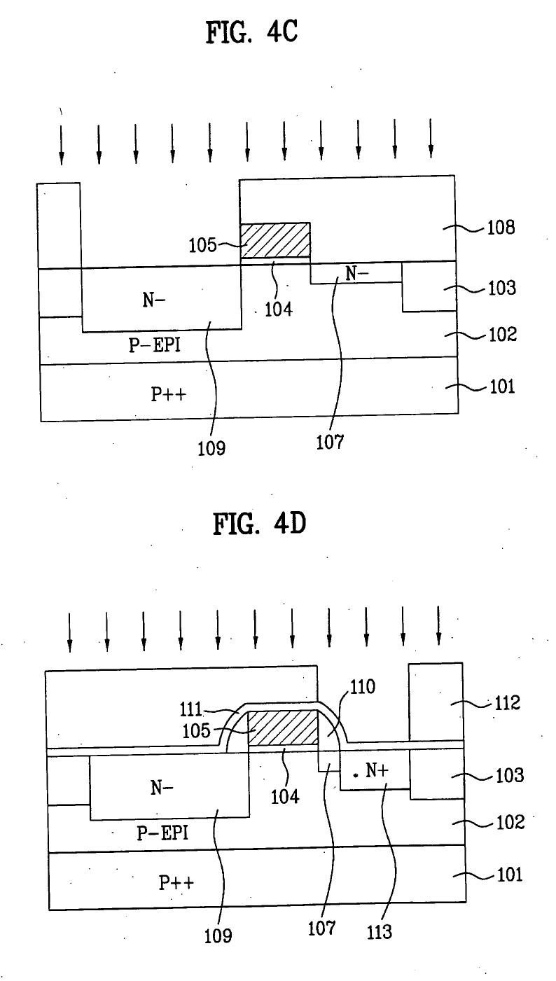

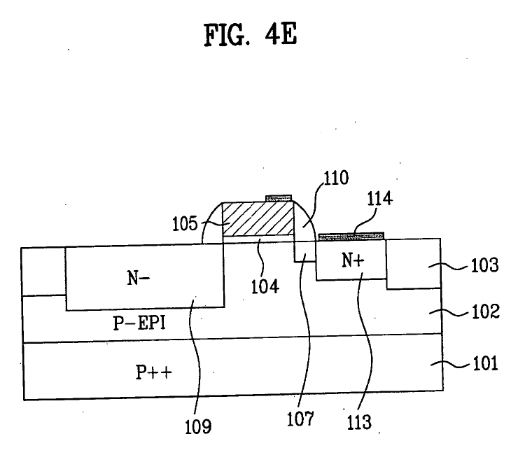

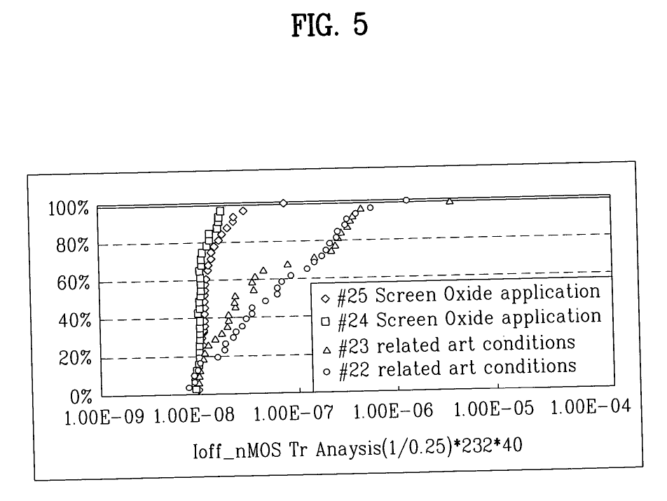

FIGS. 4A to 4E are cross sectional views of the process for fabricating a CMOS image sensor according to an embodiment of the present invention, and for comparison purposes, corresponds to the view of FIG. 3.

As shown in FIG. 4A, a lightly-doped first conductive type (P⁻-type) epitaxial layer 102 is formed in a semiconductor substrate 101 by an epitaxial process, wherein the semiconductor substrate 101 is formed of highly-doped first conductive type (P⁺⁺-type) silicon. The epitaxial layer 102 has a relatively large and deep depletion region in a photodiode, such that the capacity of low-voltage photodiode for collecting electric charges and the photosensitivity are improved.

An STI layer 103 is formed in the semiconductor substrate 101 including the epitaxial layer 102, for isolation of the device.

A method for forming the STI layer 103 will be descried as follows.

First, a pad oxide layer, a pad nitride layer and a TEOS (Tetra Ethyl Ortho Silicate) oxide layer are sequentially formed on the semiconductor substrate. Then, a photoresist is formed on the TEOS oxide layer.

Next, the photoresist is patterned by exposure and development with a mask for defining an active region and an STI region. In this case, the photoresist covering the STI region is removed.

Then, using the patterned photoresist as a mask, the pad oxide layer, the pad nitride layer and the TEOS oxide layer are removed from the STI region.

The semiconductor substrate corresponding to the STI region is etched at a predetermined depth using the patterned pad oxide layer, pad nitride layer and TEOS oxide layer as a mask, thereby forming a trench. After that, the photoresist is completely removed.

A sacrifice oxide layer is thinly formed on the entire surface of the semiconductor substrate including the trench, and an O₃ TEOS layer is formed to fill the trench. The sacrifice oxide layer is formed at the inner sidewall of the trench. The O₃ TEOS layer is formed, for example, at a temperature above 1000° C.

A CMP (Chemical Mechanical Polishing) process is then performed on the entire surface whereby the O₃ TEOS layer remains only in the trench, thereby forming the STI layer 103 inside the trench. Then, the pad oxide layer, the pad nitride layer and the TEOS oxide layer are removed.

A gate insulating layer 104 and a conductive layer (for example, highly-doped polysilicon layer) are sequentially formed on the entire surface of the epitaxial layer 102 including the STI layer 103, and are then selectively removed, thereby forming a gate electrode 105 in each of transistors. The gate insulating layer 104 may be formed by a thermal oxide process or a CVD method.

As shown in FIG. 4B, a first photoresist 106 is coated on the entire surface including the gate electrode 105, and an exposure and development process is performed to the coated first photoresist 106. Thus, the first photoresist is patterned to cover the photodiode and to expose the source and drain regions of each of the transistors.

Using the patterned first photoresist 106 as a mask, second conductivity type (n⁻-type) impurity ions are implanted into the exposed source and drain regions, thereby forming a lightly-doped n⁻-type diffusion area 107.

As shown in FIG. 4C, after completely removing the first photoresist 106, a second photoresist 108 is coated on the entire surface is then patterned to expose the photodiode by exposure and development. Using the patterned second photoresist 108 as a mask, second conductivity type (n⁻-type) impurity ions are implanted into the epitaxial layer 102, thereby forming a lightly-doped n⁻-type diffusion area 109 in the photodiode. The ion-implantation energy for the process of forming the lightly-doped n⁻-type diffusion area 109 of the photodiode is higher than that for the process of forming the lightly-doped n⁻-type diffusion area 107 of the source and drain regions. Thus, the lightly-doped n⁻-type diffusion area 109 of the photodiode is deeper and larger than the lightly-doped n⁻-type diffusion area 107 of the source and drain regions.

Referring to FIG. 4D, after completely removing the second photoresist 108, an insulating layer is formed on the entire surface of the device and it is then etched-back to form insulating sidewalls 110 on both sides of the gate electrode 105.

Subsequently, an oxide layer of TEOS type 111 is formed at a thickness of 100±30 Å on the entire surface including the gate electrode 105 and the insulating sidewalls 110. The oxide layer 111 is provided to prevent change of the device characteristics at low temperatures and to improve the device characteristics.

A third photoresist 112 is then coated on the entire surface including the oxide layer 111, and is then patterned to cover the photodiode region and the gate electrode 105 and to expose the source and drain regions in each of the transistors by exposure and development.

Using the patterned third photoresist 112 as a mask, n⁺-type impurity ions are implanted with high density into the exposed source and drain regions, thereby forming a highly-doped n⁺-type diffusion area 113. When forming the highly-doped n⁺-type diffusion area 113 according to an embodiment of the present invention, the ion-implantation energy is higher than the energy used in the related art. When forming the highly-doped n⁺-type diffusion area according to the related art, the ion-implantation energy is maintained at about 60 KeV. Instead, the formation of the highly-doped n⁺-type diffusion area according to an embodiment of the present invention is performed with an ion-implantation energy maintained at about 80 KeV.

As shown in FIG. 4E, after removing the third photoresist 112, the oxide layer 111 is removed in an isotropic wet-etching method. A salicide process is then selectively performed to the semiconductor substrate 101. Thus, a silicide layer 114 is selectively formed on the surface of the gate electrode 105 and the highly-doped n⁺-type diffusion area 113.

FIG. 5 is a simulation result of an experiment comparing the off-current characteristics in CMOS image sensors according to the related art (#22 and #23) and an embodiment of the present invention (#24 and #25).

As shown in FIG. 5, the off-current characteristics is different between the related art method for forming the CMOS image sensor (#22 and #23) and the method for forming the CMOS image sensor according to an embodiment of the present invention (#24 and #25) wherein the oxide layer was formed at a thickness of about 100 Å before implanting the impurity ions for formation of the source and drain regions.

In FIG. 5, the off-current of the transistor was measured under the same conditions for the CMOS image sensors having the transistor pattern of 232 * 40 array, according to the related art and the present invention.

The CMOS image sensor according to the related art (#22 and #23), the off-current increased as the increase of channeling probability, and the off-current value showed ununiformity having a range between 1 E⁻⁸ and 1 E⁻⁶. Accordingly, in case of the related art, it is impossible to maintain a uniform off-current. On the other hand, in the CMOS image sensor according to an embodiment of the present invention (#24 and #25), the off-current valve is uniformly maintained at 1 E⁻⁸. Also, when the channeling probability is high, the off-current value of the CMOS image sensor made by the method according to the present invention is lower than that of the CMOS image sensor made by a method according to the related art.

As mentioned above, the method for fabricating the CMOS image sensor according to the present invention has at least the following advantages.

In the method for fabricating the CMOS image sensor according to an embodiment of the present invention, the oxide layer is formed on the entire surface of the semiconductor substrate before implanting the highly-doped n⁺-type impurity ions for formation of the source and drain regions, so that it may be possible to prevent the highly-doped n⁺-type impurity ions from being permeated to the lower side of the gate electrode, thereby decreasing the off-current of the transistor. Also, it may be possible to prevent the change of device characteristics according to the temperature change.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for fabricating a CMOS image sensor comprising:
forming a gate electrode on a transistor region of a first conductivity type semiconductor substrate including a photodiode region and the transistor region;
respectively forming lightly-doped second conductivity type diffusion areas at both sides of the gate electrode in the photodiode region and the transistor region;
forming a screen layer over an entire surface of the semiconductor substrate including the gate electrode;
forming a photoresist pattern to cover the photodiode region and the gate electrode;
forming a highly-doped second conductivity type diffusion area by implanting second conductivity type impurity ions with high density into the entire surface of the semiconductor substrate using the photoresist pattern as a mask; and
removing the photoresist pattern and the oxide layer.

2. The method of claim 1, wherein the screen layer is formed of a TEOS-based oxide material.

3. The method of claim 1, wherein the screen layer comprises an amorphous layer.

4. The method of claim 1, wherein the lightly-doped second conductivity type diffusion area of the photodiode region is deeper than the lightly-doped second conductivity type diffusion area of the transistor region.

5. The method of claim 1, wherein the screen layer is formed at a thickness between 70 Å and 130 Å.

6. The method of claim 1, wherein the screen layer is removed by a wet-etching method.

7. The method of claim 1, wherein the highly-doped second conductivity type diffusion area is formed by implanting the second conductivity type impurity ions at energy of about 80 KeV.

8. The method of claim 1, further comprising:
forming an epitaxial layer by implanting first conductivity type impurity ions into the surface of the first conductivity type semiconductor substrate, wherein the density of first conductivity type impurity ions is relatively lower than the density of first conductivity type semiconductor substrate.

9. The method of claim 1, further comprising:
forming a silicide layer on the gate electrode of the transistor region and on an upper surface of the highly-doped second conductivity type diffusion area.
